(19) United States
(12) Patent Application Publication
(10) Pub. No.: US 2019/0132952 A1
(43) Pub. Date: May 2, 2019

(54) MULTILAYER CIRCUIT BOARD

(71) Applicant: FDK CORPORATION, Tokyo (JP)

(72) Inventors: Kiyoshi Oka, Tokyo (JP); Shingo Kida, Tokyo (JP); Naoki Atsumi, Tokyo (JP); Mitsuru Sato, Tokyo (JP)

(21) Appl. No.: 16/089,033

(22) PCT Filed: Mar. 16, 2017
(86) PCT No.: PCT/JP2017/010751

§ 371 Date: Sep. 27, 2018

(30) Foreign Application Priority Data
Mar. 31, 2016 (JP) 2016-071038

(51) Int. Cl. H05K 1/11; H01R 12/70

(52) U.S. Cl. CPC H05K 1/113; H01R 12/57; H01R 12/707

(57) ABSTRACT

A multilayer circuit board includes a plurality of wiring layers laminated with insulation layers interposed therebetween, the multilayer circuit board further including a solder resist layer that covers a front face wiring layer formed on a front face side insulation layer, in which the front face wiring layer includes a pad for leg terminal to which a leg terminal of a connector is connected, the solder resist layer has an opening part for leg terminal which exposes a part of the pad for leg terminal, a via for leg terminal is provided beneath the pad for leg terminal in a predetermined range straddling a contour line of an opening part for leg terminal, and the via for leg terminal connects a first internal wiring layer with the pad for leg terminal.

### TECHNICAL FIELD

The present disclosure relates to a multilayer circuit board, and more specifically to a multilayer circuit board on which a connector is mounted.

### BACKGROUND ART

An electronic apparatus includes various multilayer circuit boards. Connectors are commonly mounted on such circuit boards and used for connection with other electronic devices. A connector includes a housing for receiving a socket of a counterpart electronic apparatus, a contact pin arranged in the housing, and a signal terminal that is connected with the contact pin and protrudes from a predetermined position of the housing. The signal terminal is soldered to a dedicated pad provided on the circuit board. The pad for the signal terminal is then connected with a predetermined circuit pattern. For this reason, as a result of a socket being inserted into the housing, one electronic apparatus and another electronic apparatus are electrically connected.

When insertion or withdrawal of a socket into or from a housing of a connector is performed with a relatively large force, or the socket is twisted in a direction different from the direction of insertion/withdrawal, the connector is subjected to stress in a direction of being peeled off from the circuit board. If, in this way, stress is applied in a direction in which the connector is peeled off from the circuit board, stress is concentrated at a bonding part between a signal terminal and a pad for signal terminal, and such bonding part may be peeled off, causing bonding failure.

To suppress occurrence of such a bonding failure, there has been studied various countermeasures for preventing the housing from being peeled off with respect to the circuit board even if it is subjected to stress, thus preventing stress concentration on a bonding part. One such countermeasure is a method of fixing the housing using a reinforcement tab as shown in Japanese Laid-Open Patent No. 2006-048971. Using this reinforcement tab, it is possible to prevent the housing of a connector from being peeled off with respect to the circuit board, thereby suppressing occurrence of bonding failures even if large stress is applied from the outside.

Meanwhile, in recent years, there are demands for miniaturization of electronic apparatuses, and accordingly miniaturization has been promoted even for connectors which are mounted onto a multilayer circuit board. Such connectors (hereinafter also referred to as a miniature connectors) include USB connectors and a micro-USB connectors.

Even in such miniature connectors, it is required to suppress occurrence of bonding failures in association with application of external stress as described above.

However, since a reinforcement tab such as noted above requires a large mounting space, it hinders miniaturization of electronic module. Therefore, such a reinforcement tab is not suitable for reinforcement of miniature connectors.

Generally, in a miniature connector, a leg terminal for fixing which extends from the housing is fixed by being soldered to a pad for leg terminal provided on the circuit board. Then, a countermeasure to increase the amount of solder is taken to increase the strength of the bonding part.

### SUMMARY

If the strength of a solder bonding part is increased by increasing the amount of the solder, separation between a leg terminal and a pad for that leg terminal becomes less likely to occur. However, when stress is applied to a connector from the outside, the pad for the leg terminal may be detached from the circuit board even if the leg terminal and pad are not separated, and accordingly the pad can be peeled from the circuit board, thus causing a bonding failure.

For this reason, trials have been performed to prevent peeling off of such pads by causing a solder resist layer to be overlapped on a peripheral edge part of the pad for leg terminal and the pad for signal terminal.

However, if large stress is applied multiple times in a random direction to a miniature connector from a user, it is difficult to sufficiently prevent peeling off of the pad only by coating of the solder resist as described above. For this reason, in general, a countermeasure to prevent peeling off of the bonding part by performing reinforcement by coating reinforcement resin so as to cover the solder bonding part on the circuit board.

Now, coating of reinforcement resin as described above must be performed for a predetermined range after the end of soldering, which increases working hours. Moreover, coating the reinforcement resin on minute portions becomes tedious work, and takes time. Further, material cost of the reinforcement resin will also increase. Since, for this reason, reinforcement countermeasure by coating reinforcement resin deteriorates production efficiency of multilayer circuit boards and increases the manufacturing cost, omission of such countermeasure is desirable.

The present disclosure has been made based on the above described circumstances, and its objective is to provide a multilayer circuit board which can prevent the pad from being peeled off even if reinforcement resin is not coated, and thus reducing manufacturing cost.

In order to achieve the above object, an aspect of the present disclosure is directed to a multilayer circuit board including a plurality of wiring layers laminated with insulation layers interposed therebetween, wherein the multilayer circuit board includes a solder resist layer which covers a front face wiring layer located on an outermost front face side of the plurality of wiring layers, wherein the front face wiring layer includes a pad to which a terminal of a connector is bonded, the connector being mounted to a front face of the multilayer circuit board, the solder resist layer has an opening part which exposes a part of the pad, a via is provided in a predetermined range which straddles a contour line of the opening part beneath the pad, and the via connects an internal wiring layer located inside the multilayer circuit board out of the wiring layers with the pad.

Here, in a preferred aspect, the vias are provided in plural numbers along the contour line.

Moreover, in a preferred aspect, of the internal wiring layers described above, the internal wiring layer located in the same layer is connected with two or more vias.

In a more preferable aspect, the opening part has a rectangular shape in a plan view, and the via is respectively provided in a portion of corner and a portion of side of the rectangular shape.

Further, in a preferred aspect, the via extends to a back face wiring layer located at utmost back face side of the wiring layer, thereby connecting the pad, the internal wiring layer, and the back face wiring layer.

When a terminal of a connector is soldered to a pad, a solder bonding part is formed in the pad, and a tip end of the solder boding part is positioned to a portion of contour line of the opening part in the solder resist layer. Then, when stress is applied to the connector from the outside, stress is likely to be concentrated to a tip end of the solder bonding part, that is, a portion of contour line of the opening part in the solder resist layer. The multilayer circuit board of the present disclosure is configured such that a via is provided in a predetermined range straddling the contour line of the opening part beneath the pad, and the via connects the pad with the internal wiring layer. Since a via connected with the internal wiring layer is present in a portion to which stress is likely to be concentrated, such a via exerts anchor effect, making it possible to sufficiently prevent peeling off of the pad even without performing coating of reinforcement resin.

Therefore, according to the present disclosure, it is possible to provide a multilayer circuit board which can prevent a pad from being peeled off even without coating a reinforcement resin, thus making it possible to reduce the production cost.

### BRIEF DESCRIPTION OF THE DRAWINGS

FIG. 1 is s perspective view to schematically show a configuration of a connector seen from an insertion inlet side, and a configuration of a connector seen from the rear wall side.

FIG. 2 is a plan view to show a part of the multilayer circuit board according to a first embodiment.

FIG. 3 is a sectional view taken along a III-III line of FIG. 2.

FIG. 4 is a sectional view taken along a IV-IV line of FIG. 2.

FIG. 5 is a sectional view corresponding to FIG. 3 in the multilayer circuit board according to a second embodiment.

FIG. 6 is a sectional view corresponding to FIG. 4 in the multilayer circuit board of the second embodiment.

### DETAILED DESCRIPTION

### First Embodiment

A multilayer circuit board 1 according to the present disclosure will be described below with reference to the drawings.

The multilayer circuit board 1 is a multilayer circuit board made up of a large number of wiring layers laminated with insulation layers interposed therebetween. Various electronic parts and a connector are mounted at predetermined positions of the multilayer circuit board.

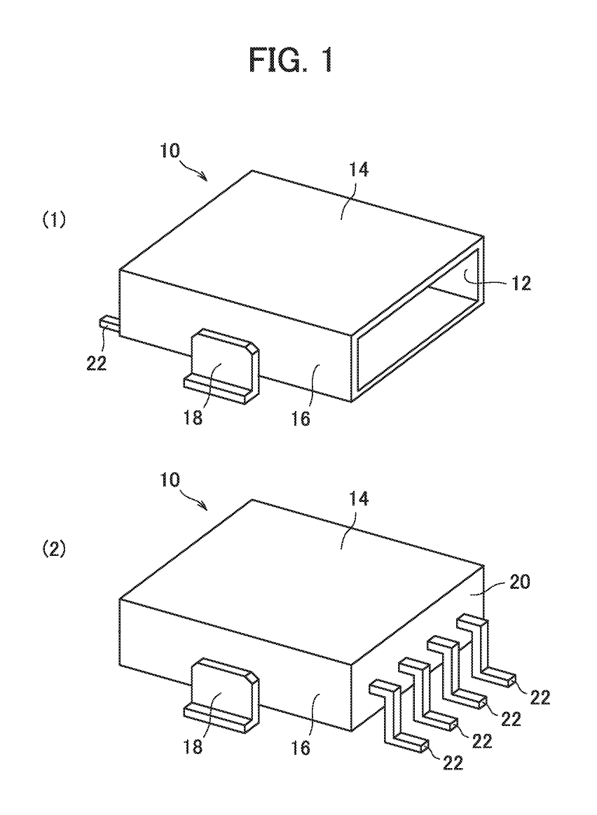

A connector 10 includes, as shown in (1) and (2) of FIG. 1, a housing 14 having an insertion port 12 into which a socket (not shown) of another electronic part is inserted, a leg terminal 18 arranged on each side wall 16 of the housing 14, and a signal terminal 22 protruding from a rear wall 20 of the housing 14, which is located on opposite side of the insertion port 12.

The connector 10 is mounted as a result of the leg terminal 18 and the signal terminal 22 being soldered to predetermined positions of the front face of the multilayer circuit board 1.

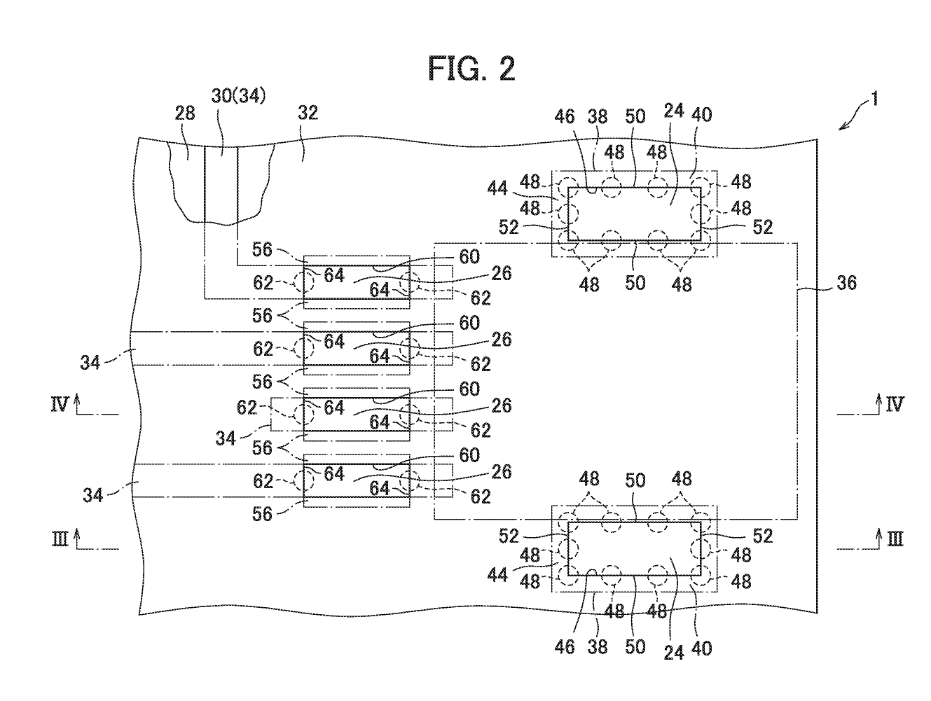

In a portion to which the connector 10 is mounted on the front face of the multilayer circuit board 1, as shown in FIG. 2, a pad 24 for leg terminal to which the leg terminal 18 of the connector 10 is bonded, and a pad 26 for signal terminal to which the signal terminal 22 of the connector 10 is bonded are provided.

The pad 24 for leg terminal and the pad 26 for signal terminal are formed as a result of a predetermined site of the front face wiring layer 30, which is provided on the front face side insulation layer 28 located on the utmost front face side of the multilayer circuit board 1, being processed into a predetermined shape. Note that the front face wiring layer 30 forms, besides that, a wiring pattern 34 of a predetermined shape as well.

Here, in the front face side insulation layer 28 and the front face wiring layer 30, a solder resist layer 32 is provided on a portion where contact with the solder should be avoided. Since portions of the pad 24 for leg terminal and the pad 26 for signal terminal as described above conversely need to come into contact with the solder to form a solder bonding part, the solder resist layer 32 is not provided on the pad 24 for leg terminal and the pad 26 for signal terminal, and these pads are partially exposed.

The pad 24 for leg terminal is provided, as obvious from FIG. 2, at a predetermined position where the leg terminal 18 arranged on each side wall 16 of the housing 14 are respectively positioned when the connector 10 is set to an intended mounting site 36. The pad 24 for leg terminal has a rectangular shape in a plan view, and a range (hereafter, referred to as an outer peripheral edge part 40) which extends inwardly from the outer peripheral edge 38 by a predetermined length is covered with the solder resist layer 32. Then, in the pad 24 for leg terminal, a portion excepting the outer peripheral edge part 40, that is, a portion which is not covered with the solder resist layer 32, is exposed.

Here, in the solder resist layer 32, a portion which is overlapped with the outer peripheral edge part 40 of the pad 24 for leg terminal is referred to as an overlapped part 44, and a portion which exposes the pad 24 for leg terminal is referred to as an opening part (hereinafter, referred to as an opening part 46 for leg terminal). The opening part 46 for leg terminal forms a rectangular contour which is similar to a reduced shape of the contour of the pad 24 for leg terminal.

In the present embodiment, a via (hereinafter, referred to as a via 48 for leg terminal) is provided in a predetermined range straddling a contour line of the opening part 46 for leg terminal of the above described solder resist layer 32 beneath the pad 24 for leg terminal. Specifically, as described by an imaginary circle in FIG. 2, the via 48 for leg terminal is provided along the contour line of the rectangular of the opening part 46 for leg terminal. More specifically, a total of ten vias 48 for leg terminal: one for each portion of four corners of the contour line of a rectangular; two for a portion of long side 50 of the contour line of the rectangular; and one for each portion of short side 52 of the contour line of the rectangular, are provided per one pad 24 for leg terminal.

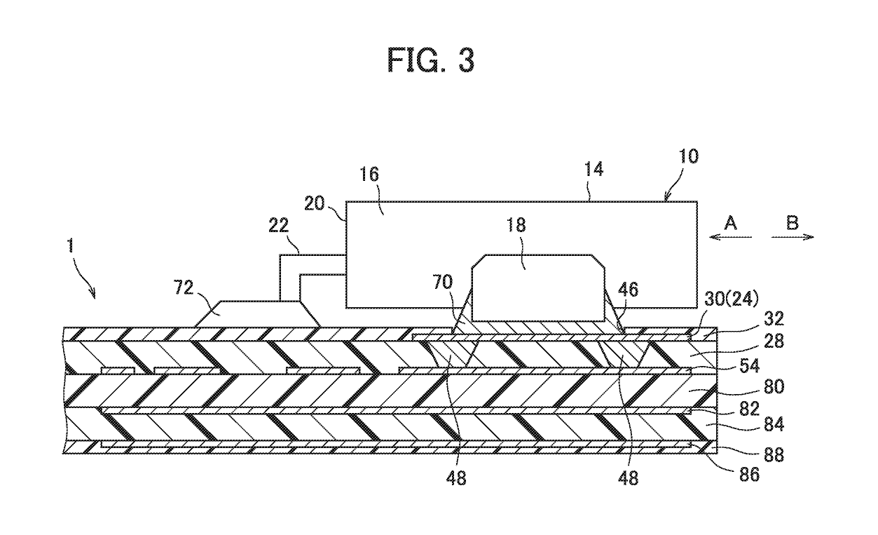

The via 48 for leg terminal reaches a first internal wiring layer 54 which is the wiring layer of the second layer, supposing that the front face wiring layer 30 is the wiring layer of the first layer, as shown in FIG. 3, thereby connecting the first internal wiring layer 54 and the pad 24 for leg terminal.

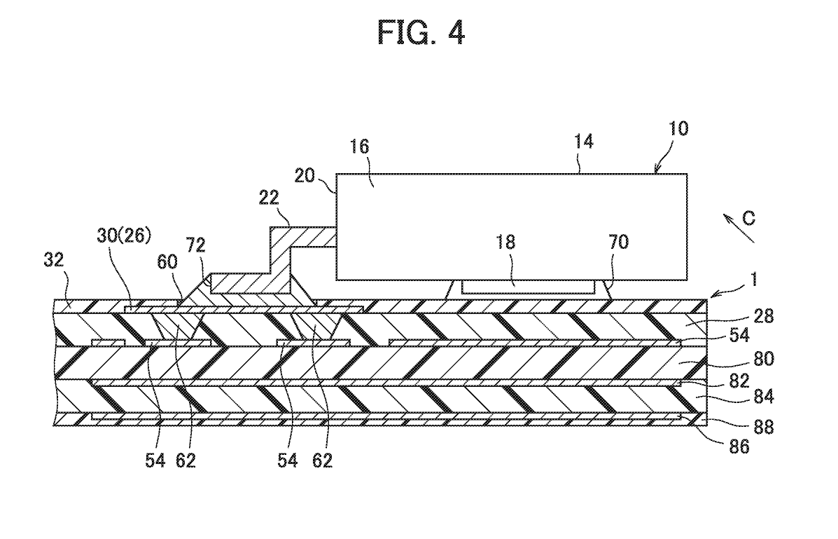

Here, in FIG. 3, reference sign 80 shows a central insulation layer; reference sign 82 a second internal wiring layer which is a wiring layer of the third layer; reference sign 84 a back face side insulation layer; reference sign 86 a back face wiring layer; and reference sign 88 a back face side solder resist layer, respectively. Note that the same applies to FIGS. 4 to 6 described below.

On the other hand, the pad 26 for signal terminal is provided at a predetermined position where the signal terminal 22 protruding from the rear wall 20 of the housing 14, when the connector 10 is set to an intended mounting site 36 as shown in FIG. 2.

The pad 26 for signal terminal is formed by processing a part of the wiring pattern 34 of the front face wiring layer 30 to have a wide width, and has a rectangular shape in a plan view. In this pad 26 for signal terminal, a portion (hereinafter, referred to as an expanded width part 56) which is expanded further than the width of the wiring pattern 34 is covered with a solder resist layer 32, and a portion having the same width as that of the wiring pattern 34 is exposed. That is, in the solder resist layer 32 of a portion where each pad 26 for signal terminal is present, a rectangular opening part (hereinafter, referred to as an opening part 60 for signal terminal) is provided as obvious from FIG. 2.

In the present embodiment, a via (hereinafter, referred to as a via 62 for signal terminal) is provided in a predetermined range straddling a contour line of the opening part 60 for signal terminal of the solder resist layer 32 beneath the pad 26 for signal terminal. Specifically, as described by an imaginary circle in FIG. 2, a via 62 for signal terminal is provided in a portion of a shorter side 64 of the contour line of a rectangular of the opening part 60 for signal terminal.

More specifically, per one pad 26 for signal terminal, a total of two vias for signal terminal 62: one for each portion of short side 64 of the contour line of a rectangular are provided for one pad 26 for signal terminal.

Note that if there is margin between each signal terminal, configuration may be such that a pattern width of the signal terminal is expanded, a via 62 for signal terminal is provided in a portion of long side of the opening part 60 for signal terminal, and a solder resist is coated on the long side of the signal terminal.

The via 62 for signal terminal reaches the first internal wiring layer 54, which is the second wiring layer, letting the front face wiring layer 30 be the first wiring layer, thus connecting the first internal wiring layer 54 and the pad 26 for signal terminal, as shown in FIG. 4.

Such a multilayer circuit board 1 can be manufactured by a conventionally used manufacturing method such as a build-up method to manufacture multilayer circuit boards. In that case, the front face wiring layer 30, the first internal wiring layer 54, the solder resist layer 32, each insulation layer, the pad 24 for leg terminal, the pad 26 for signal terminal, the via 48 for leg terminal, the via 62 for signal terminal, and so on are provided such that the above described positional relationship is realized. Further, the method for forming the via 48 for leg terminal and the via 62 for signal terminal is not specifically limited, and they are formed by a generally used method. At this time, the interior of each via is preferably a filled via which is filled with copper plating.

On the multilayer circuit board 1 including the via 48 for leg terminal and the via 62 for signal terminal, various electronic parts and the connector 10 are mounted by being soldered.

When the connector 10 is soldered, the leg terminal 18 is bonded onto the pad 24 for leg terminal via a solder bonding part 70, and the signal terminal 22 is bonded to the pad 26 for signal terminal via a solder bonding part 72, as shown in FIGS. 3 and 4.

Here, for example, when a user performs withdrawal and insertion of a socket from and into the connector 10 multiple times, thereby repeatedly applying large stress in an arrow A direction and an arrow B direction shown in FIG. 3, or applies large stress in a direction different from the regular withdrawal and insertion direction such as an arrow C direction of FIG. 4, stress is likely to be concentrated at a tip end of the solder bonding part 70, 72, that is, a tip end portion of a solder fillet. Since generally the tip end portion of the solder fillet extends to a portion of contour line of an opening part (opening part 46 for leg terminal, opening part 60 for signal terminal) of the solder resist layer 32, a tip end portion of the solder fillet is positioned in the vicinity of the contour line. Therefore, the vicinity of the contour line of the opening part of the solder resist layer 32 in a pad (pad 24 for leg terminal, pad 26 for signal terminal) is likely to be subjected to stress, and peeling off is likely to occur with such a portion as a starting point. For such a situation, in the multilayer circuit board 1 of the present embodiment, the via 48 for leg terminal and the via 62 for signal terminal are present beneath the contour line of the opening part of the solder resist layer 32, and these vias connect the pads (pad 24 for leg terminal, pad 26 for signal terminal) with the first internal wiring layer 54. Since these vias exert anchor effect, they can effectively prevent the pad from being peeled off even if stress is applied to the pad portion. Therefore, it is possible to obviate the need of reinforcement with reinforcement resin.

### Second Embodiment

Hereinafter, a second embodiment will be described as another embodiment. Upon this description, only portions which are different from those of the first embodiment will be described, and for like portions as those of the first embodiment, detailed description will be omitted by using like reference signs.

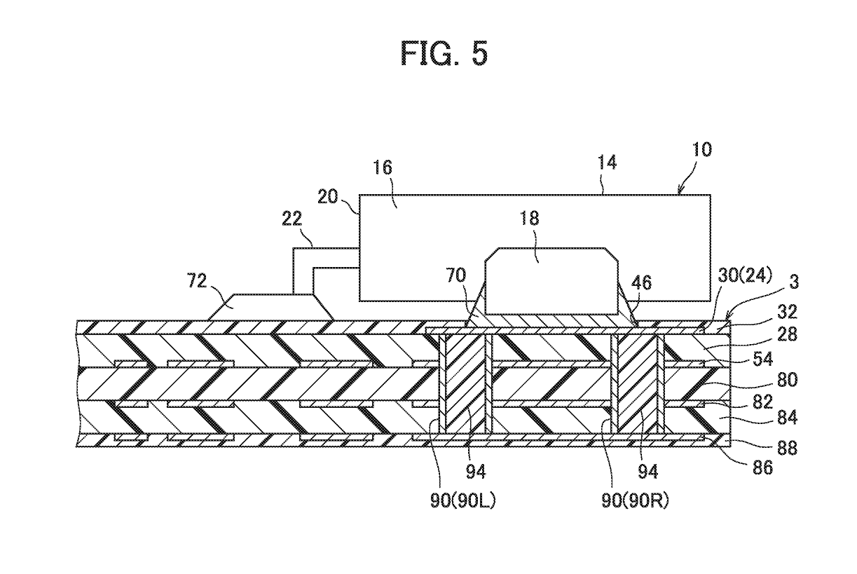

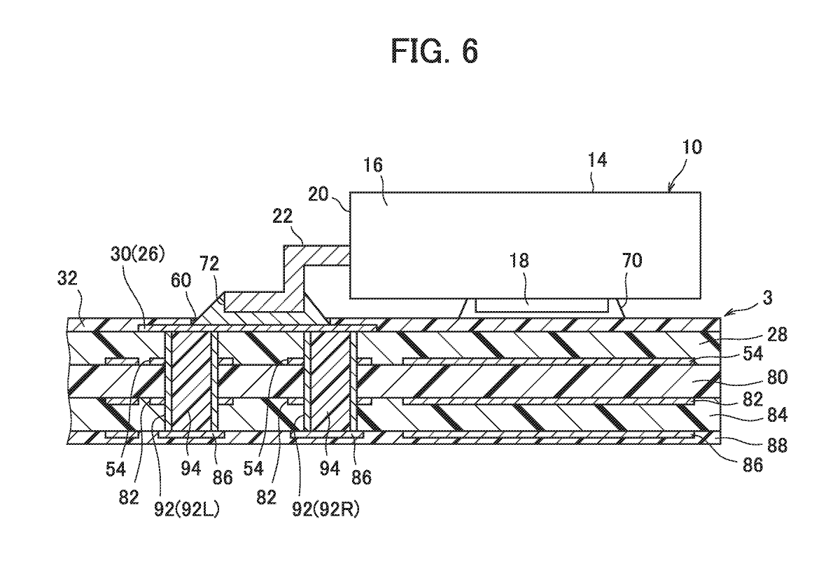

A multilayer circuit board 3 of the second embodiment is, as shown in FIGS. 5 and 6, the same as that of the first embodiment excepting that a through via extending from the front face wiring layer 30 to the first internal wiring layer 54, the second internal wiring layer 82, and the back face wiring layer 86 is used as a via 90 for leg terminal and a via 92 for signal terminal.

Formation of the through via is not specifically limited, and it can be formed by a general forming method. In the present embodiment, the interior of the through via is filled with resin 94. That is, the via 90 for leg terminal and the via 92 for signal terminal are hole-filling through vias.

According to the multilayer circuit board 3 of the second embodiment, since the vias located beneath the pad 24 for leg terminal and the pad 26 for signal terminal reach not only the first internal wiring layer 54, but also the second internal wiring layer 82 and the back face wiring layer 86 on the back face side to be connected with these layers, an anchor effect stronger than that of the first embodiment is obtained. For that reason, when stress is applied to the connector 10, it is possible to more reliably suppress the occurrence of a failure that a pad is peeled off when stress is applied to the connector 10.

Here, as shown in FIG. 6, beneath the pad 26 for signal terminal, the first internal wiring layer 54 and the second internal wiring layer 82 are divided between a via 92R for signal terminal on the right side in FIG. 6 and a via 92L for signal terminal on the left side in FIG. 6. On the other hand, as shown in FIG. 5, beneath the pad 24 for leg terminal, the first internal wiring layer 54 and the second internal wiring layer 82 are connected between a via 90R for leg terminal on the right side in FIG. 5 and a via 90L for leg terminal on the left side in FIG. 5. In this way, it is possible to increase the area in contact with an insulation layer in the internal wiring layer which is connected with a via, in a configuration (hereinafter, referred to as a connected configuration) in which the internal wiring layer of the same layer is connected between two or more vias compared with in a configuration (hereinafter, referred to as a divided configuration) in which the internal wiring layer is divided between vias. Therefore, the internal wiring layer connected with the via can resist more strongly against stress applied in a direction in which the pad is peeled off, that is, a direction in which the via is withdrawn, in the connected configuration than in the divided configuration, thus exerting larger anchor effect, which is therefore preferable. Note that when the above described connected configuration is adopted, it is more preferable to arrange the internal wiring layer at a shortest distance between two or more vias. This is because connecting vias at a shortest distance in that way increases integrity among vias, further enhancing the anchor effect.

Note that the fact that more excellent anchor effect can be obtained in a connected configuration compared with in a divided configuration, will not be limited to through vias, and the same applies to a via which extends only to the internal wiring layer on a middle way without passing through to the back face wiring layer.

Note that the present invention will not be limited to the above described embodiments, and various variations thereof are possible. For example, the forming position and the number of vias can be arbitrarily set. Moreover, wiring layers to be connected with the vias can be arbitrarily set as well. Further, the shape of the pad will not be limited to a rectangle, and may be arbitrarily selected, such as to be polygonal, circular, elliptic, and so on.

### EXPLANATION OF REFERENCE SIGNS

1 Multilayer circuit board
3 Multilayer circuit board
10 Connector
18 Leg terminal
22 Signal terminal
24 Pad for leg terminal
26 Pad for signal terminal
28 Front face side insulation layer
30 Front face wiring layer
32 Solder resist layer
46 Opening part for leg terminal
48 Via for leg terminal
54 First internal wiring layer
60 Opening part for signal terminal
62 Via for signal terminal

1. A multilayer circuit board comprising a plurality of wiring layers laminated with insulation layers interposed therebetween, wherein
the multilayer circuit board comprises a solder resist layer which covers a front face wiring layer located on an outermost front face side of the plurality of wiring layers, wherein
the front face wiring layer includes a pad to which a terminal of a connector is bonded, the connector being mounted to a front face of the multilayer circuit board,
the solder resist layer has an opening part which exposes a part of the pad,
a via is provided in a predetermined range which straddles a contour line of the opening part beneath the pad, and
the via connects an internal wiring layer located inside the multilayer circuit board out of the wiring layers with the pad.

2. The multilayer circuit board according to claim 1, wherein
the via is provided in a plural number along the contour line.

3. The multilayer circuit board according to claim 2, wherein
an internal wiring layer, which is located in a same layer, out of the internal wiring layers is connected with two or more vias out of the plural vias.

4. The multilayer circuit board according to claim 1, wherein
the opening part has a rectangular shape in a plan view, and the via is provided respectively at a portion of corner and a portion of side in the rectangular shape.

5. The multilayer circuit board according to claim 1, wherein
the via extends to a back face wiring layer which is located on utmost back face side of the wiring layers, to connect the pad, the internal wiring layer, and the back face wiring layer.
